(19) United States
(12) Patent Application Publication
(10) Pub. No.: US 2023/0099748 A1
(43) Pub. Date: Mar. 30, 2023

(54) ENERGY CONSUMPTION FILTERING DEVICE FOR NEW ENERGY ELECTRIC VEHICLE BASED ON SIC MODULE

(71) Applicant: Huaihua Yaxin Electronics Co., Ltd., Huaihua (CN)

(72) Inventor: Daidong JIN, Huaihua (CN)

(73) Assignee: Huaihua Yaxin Electronics Co., Ltd., Huaihua (CN)

(21) Appl. No.: 17/542,955

(22) Filed: Dec. 6, 2021

(30) Foreign Application Priority Data
Sep. 29, 2021 (CN) 202111152603X

(51) Int. Cl. B60R 16/02

(52) U.S. Cl. CPC B60R 16/02; H03H 2001/0021

(57) ABSTRACT

An energy consumption filtering device for a new energy electric vehicle based on a SiC module is provided, related to the field of new energy vehicles. The problem to be solved in the solution is that when the filter device is installed for the existing installation device, the adaptive adjustment can not be made according to different requirements, and the practicability of the device is reduced. The embodiments include a limit device, a guide device, a support device, a mounting support plate and a new energy vehicle filter, where a lower end face of the limit device is symmetrically engaged with the support device for a limit by sliding thread, and the lower end face of the limit device is symmetrically and elastically engaged with the guide device for the limit by sliding with the guide device as an axis.

### CROSS-REFERENCE TO RELATED APPLICATIONS

The application claims priority to Chinese patent application No. 202111152603X, filed on Sep. 29, 2021, the entire contents of which are incorporated herein by reference.

### TECHNICAL FIELD

The disclosure relates to the field of new energy vehicles, in particular to an energy consumption filtering device for a new energy electric vehicle based on a SiC module.

### BACKGROUND

The new energy vehicle refers to the vehicle that uses unconventional vehicle fuel as the power source, integrates the advanced technology of vehicle power control and driving, and forms an advanced technical principle, new technology and new structure. At present, the driving system of the new energy vehicle is a variety of motors and motor controllers, but the controller will cause electromagnetic interference when it works. The new energy electric vehicle can limit the interference through the filter device, so as to improve the working efficiency of the new energy electric vehicle. However, the existing energy consumption filter device of the new energy electric vehicle is easy to generate accumulated heat when it is used. Moreover, the existing installation device has insufficient heat dissipation, thus reducing the service life of the filter device. Meanwhile, when the existing installation device is installed on the filter device, it can not be adjusted according to different requirements, which reduces the practicability of the device.

Through patent retrieval, the following known prior art solutions exist:

patent 1: application number, CN202010899331.9, application date: Aug. 31, 2020, authorization announcement date: Nov. 13, 2020, and the disclosure provides an energy consumption measuring device for an electric vehicle based on a SiC module consumption measuring device for an electric vehicle based on a SiC module, comprising a lifting device for lifting an electric vehicle and a dynamometer for measuring wheel power; the dynamometer comprises four, each wheel is correspondingly provided with a dynamometer, each dynamometer is connected with an SIC module, and a plurality of SIC modules are connected with a main control device through a communication line; the test shaft of the dynamometer is connected with a drive shaft of the wheel through a connector. The energy consumption measuring device for an electric vehicle based on a SiC module created by the disclosure can test the overall energy consumption of the electric vehicle in combination with the battery power and the measured power of each wheel, and can effectively test the overall energy consumption of the electric vehicle to obtain the power conversion rate.

Patent 2: application No., CN201120438780.X, application date: Nov. 8, 2011, authorization announcement date: Aug. 1, 2012, and the disclosure relates to a new energy vehicle filtering device and a vehicle using the device. The new energy vehicle filtering device is installed between the motor controller and the motor, and comprises a three-phase filtering inductor, a ferrite ring and a three-phase filtering capacitor, wherein each three-phase line at one end of the three-phase filtering inductor is respectively connected with a corresponding three-phase line at the output end of the motor controller; each three-phase line at the other end of the three-phase filtering inductor is respectively connected with a corresponding three-phase line at the input end of the motor; the ferrite magnetic ring is sleeved on the three-phase line between the three-phase filtering inductor and the motor; one end of the three-phase filtering capacitor is connected with the three-phase line between the ferrite ring and the motor, and the other end is grounded. The structure of the device is simple, the filtering effect is good, and it can filter the interference waveform produced by the motor and the controller.

Through the above search, it is found that the above technical solution can not affect the novelty of the present disclosure, and the combination of the above patent documents can not destroy the inventive step of the present disclosure.

### SUMMARY

The technical problem to be solved in the technical solution is that when the filter device is installed for the existing installation device, the adaptive adjustment can not be made according to different requirements, and the practicability of the device is reduced.

In order to achieve the above objects, the disclosure creates an energy consumption filtering device for a new energy electric vehicle based on a SiC module, comprising: a limit device, a guide device, a support device, a mounting support plate and a new energy vehicle filter, wherein a lower end face of the limit device is symmetrically engaged with the support device for a limit by sliding thread, and the lower end face of the limit device is symmetrically and elastically engaged with the guide device for the limit by sliding with the guide device as an axis, and a lower end face of the new energy vehicle filter is symmetrically and fixedly connected with the mounting support plate for a connection.

The technical scheme has the following benefits: during installation, the user can align the limit device with the new energy vehicle filter, and then position the new energy vehicle filter between two groups of guide devices, at this time, the guide device can shrink to the inside elastically, and the connecting leg at the bottom of the guide device can limit the new energy vehicle filter, and then the user can screw the connecting disk according to the requirements, when the connecting disk rotates, the connecting disk can drive the fixed conical toothed disk to rotate, and when the fixed conical toothed disk rotates, the fixed conical toothed disk can drive the connecting screw at the side to rotate synchronously, furthermore, since the external part of the connecting screw is threadedly connected with the supporting device, the user can adjust the specific position of the supporting device back and forth by connecting the rotary table until the rear part of the heat conduction blade is completely clamped and fitted with the filter of the new energy vehicle, and then the installation operation is completed, which can effectively improve the adaptability of the device.

The technical problem to be solved by the improvement of the technical scheme is that the existing new energy electric vehicle energy consumption filtering device is easy to generate heat accumulation when used, and the existing installation device has insufficient heat dissipation, thereby reducing the service life of the filtering device.

In order to achieve that above object, the disclosure create an improved technical scheme: the limit device comprises a guide chute, a bevel gear, a fixed bevel gear disk, a connecting disk, a connecting screw, a connecting fan, a fixed chute and a limit chuck, a lower end face of the limit chuck is symmetrically provided with the fixed chute for positioning, and the guide chute is symmetrically formed on the lower end surface of the limit chuck with the fixed chute as the axis, an inner end surface of the limit chuck is rotationally clamped with a fixed conical toothed disk for transmission, and the connecting disk is fixedly connected at a center of an upper end surface of the fixed conical toothed disk, an upper end surface of the limit chuck is symmetrically clamped with two groups of connecting fans, and the inner end surface of the limit chuck is rotationally clamped with the connecting screw, and the bevel gear is fixedly installed at a center of a front end face of the connecting screw.

The improved technical scheme has the following beneficial effects: during the heat dissipation operation, the user can simultaneously start four groups of connecting fans through the external control device, at this time, the connecting the connecting fans can rotate at high speed, and then blast the bottom of the limit bracket for heat dissipation; meanwhile, the rear part of the fixed base plate and the guide carriage are mortgaged with the outside of the new energy automobile filter, so that the outside of the guide device and the new energy automobile filter are bonded with the new energy automobile filter; when the new energy automobile filter generates a large amount of heat, the heat can be directly guided to the outside of the fixed base plate and the guide carriage through heat transfer, at the same time, the heat-dissipating blade outside the fixed base plate and the heat-conducting blade outside the guide slide seat can cooperate with the connecting fan, and the maximum transmission improves the heat-dissipating efficiency of the new energy vehicle filter.

The technical problem to be solved in the improvement of the technical scheme is that the stability of the limit is insufficient when the filter device is installed and protected.

In order to achieve the above objects, the disclosure creates an improved technical solution: the guide device comprises a spring snap ring, a guide slider, a fixed base plate, a heat dissipation blade plate and a connecting leg, wherein a rear end surface of the fixed base plate is fixedly connected with the heat dissipation blade plate for heat dissipation uniformly and equidistantly, and the guide slider is fixedly connected at a center of an upper end surface of the fixed base plate, the spring snap ring is fixedly connected at a center of a front end surface of the guide slider, and a lower end surface of the fixed base plate is fixedly connected with the connecting leg.

The improved technical scheme has the beneficial effect that: the connecting leg can stably limit the bottom of the new energy vehicle filter, and the spring snap ring can provide sufficient elasticity for the fixed base plate, so that the interior of the fixed base plate can always fit with the interior of the new energy vehicle filter, so as to facilitate the subsequent adaptation of different types of new energy vehicle filters, and at the same time, improve the stability of the device to limit the new energy vehicle filter.

The technical problem to be solved in the improvement of the technical scheme is that the stability and adaptability of the limit are insufficient when the filter device of different sizes is limited.

In order to achieve the above objects, the technical scheme adopted after the improvement is created by the disclosure: the supporting device comprises a heat-conducting blade, a connecting spring, a supporting slide plate, a clamp seat and a guide slide seat, wherein a fixed clamp seat is fixedly mounted on the upper end surface of the supporting slide plate, and the guide slide seat is symmetrically slidably clamped on an upper end surface of the fixed clamp seat; two groups of guide slide seats are elastically fixedly connected through the connecting spring, and an upper end surface of the guide slide seat is fixedly connected with a heat conduction blade at uniform and equal intervals.

The improved technical scheme has the benefits that the two groups of guide slide seats can be slidably clamped in the interior of the fixed clamp seat, and the two groups of guide slide seats can be elastically connected through the connecting spring, so that the two groups of guide slide seats have enough limit space, so as to facilitate the limit clamping of the new energy vehicle filter by the follow-up guide device, and improve the adaptability of the device.

The technical problems to be solved in the improvement of the technical scheme is that the stability of the device is insufficient during installation and transmission, and the protection against the filter device is reduced.

In order to achieve the above objects, the disclosure creates an improved technical solution: a support shaft is fixedly connected at a center of an inner end surface of the fixed chute, and a support guide groove is formed in an inner end surface of the guide slider through inner and outer sides, and the support guide groove is aligned with the spring snap ring.

The improved technical scheme has the benefits that: the supporting shaft and the spring snap ring are aligned, so that the subsequent spring snap ring can be quickly and stably positioned inside the fixed chute, and the supporting groove and the supporting shaft can provide sufficient limit foundation for the guide slider, so as to improve the stability of the subsequent guide device to limit the new energy vehicle filter, and also improve the protection of the new energy vehicle filter.

The technical problem to be solved in the improvement of the technical scheme is that the stability of the guidance between the devices is insufficient, thus reducing the stability of the subsequent installation of the filter device.

In order to achieve the above objects, the disclosure creates an improved technical solution: the support guide groove is matched with the support shaft, and the guide device is matched with the support shaft through the support guide groove so as to be slidably engaged with the inner end face of the fixed chute.

The beneficial effect of the improved technical scheme is that the double limit of the support shaft and the support guide groove can effectively improve the stability of the displacement of the guide device, and further improve the stability of the limit installation of the new energy vehicle filter.

The technical problem to be solved in the improvement of the technical scheme is that the stability of the device is insufficient during transmission, which reduces the stability of the subsequent limit of the filter device of different sizes.

In order to achieve the above objects, the disclosure creates an improved technical solution: the bevel gear is meshed and rotationally connected with the fixed bevel gear disk, and the fixed bevel gear disk is rotationally engaged with the inner end face of the limit chuck by connecting the connecting disk.

The improved technical scheme has the beneficial effect of fixing the meshing relationship between the conical gear and the conical gear, which can effectively improve the stability and efficiency of the connecting screw transmission, and further facilitate the stability of the limit of the filter of the new energy vehicle with different sizes.

The technical problem to be solved by the improvement of the technical scheme is that the accuracy of the limit is insufficient when the filter device is limited.

In order to achieve the above objects, the disclosure creates an improved technical solution: the connecting screw is adapted to the supporting slide plate, and the support device is adapted to the supporting slide plate by the connecting screw so as to be slidably engaged with a bottom end surface of the limit chuck.

The improved technical scheme has the beneficial effect that the threaded connection between the connecting screw and the supporting sliding plate can facilitate the user to adjust the limit space during the installation of the filter of the new energy vehicle, and the relationship of the threaded connection can effectively improve the accuracy of the limit.

### BRIEF DESCRIPTION OF DRAWINGS

FIG. 1 is an exploded view of the main body of the present disclosure;

FIG. 2 is an assembly diagram of the main body of the present disclosure;

FIG. 3 is an exploded view of a limit device of the present disclosure;

FIG. 4 is an assembly diagram of a limit device of the present disclosure;

FIG. 5 is a schematic structural diagram of a guide device of the present disclosure;

FIG. 6 is a schematic structural diagram of a support device according to the present disclosure.

### DETAILED DESCRIPTION OF THE EMBODIMENTS

In order for those skilled in the art to better understand the technical solution of the present disclosure, the present disclosure is described in detail below in combination with the drawings. The description of this part is only exemplary and explanatory, and the scope of protection of the present disclosure shall not be limited.

### Embodiment 1

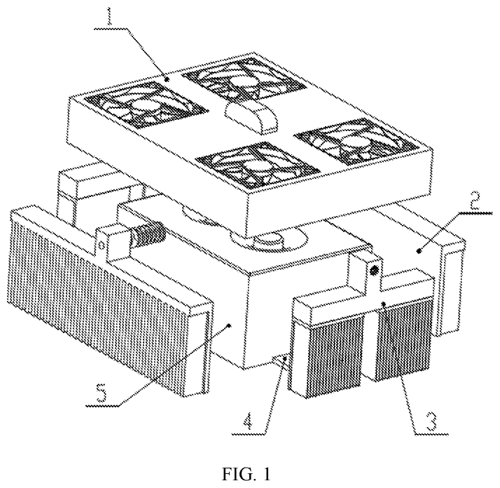

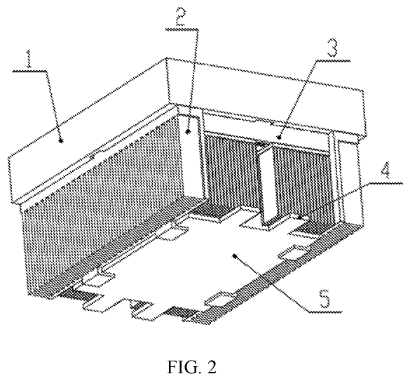

as shown in FIG. 1 to FIG. 2, an energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. During installation, the user can align the limit device 1 with the new energy vehicle filter 5, and then position the new energy vehicle filter 5 between the two sets of guide devices 2. At this time, the guide device 2 can be retracted to the inside elastically, and at the same time, the connecting leg 25 at the bottom of the guide device 2 can limit the new energy vehicle filter 5, and then the user can screw the connecting disk 14 as required. When the connecting disk 14 rotates, the connecting disk 14 can drive the fixed conical toothed disk 13 to rotate, and when the fixed conical toothed disk 13 rotates, the fixed conical toothed disk 13 can drive the connecting screw 15 at the side to rotate synchronously. Furthermore, since the connection screw 15 is threadedly connected to the support device 3 from the outside, the user can adjust the specific position of the support device 3 back and forth through the connection rotary table 14 until the rear part of the heat conduction blade 31 is completely clamped and fitted with the new energy vehicle filter 5, thus completing the installation operation and effectively improving the adaptability of the device.

### Embodiment 2

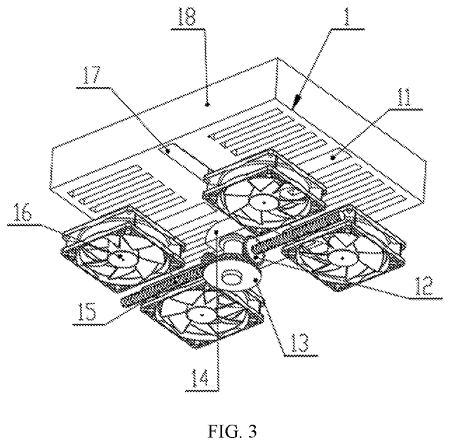

as shown in FIG. 1 to FIG. 3, as a further optimization of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. In the heat dissipation operation, the users can simultaneously start the four groups of connecting fans 16 through the external control device, and at this time, the connecting fan 16 can rotate at a high speed, thereby blowing heat to the bottom of the limit chuck 18, and at the same time, the rear part of the fixed base plate 23 and the guide slide seat 35 are mortgaged with the outside of the new energy vehicle filter 5, so that the outside of the guide device 2 and the new energy vehicle filter 5 are bonded with the new energy vehicle filter 5, and when the new energy vehicle filter 5 generates a large amount of heat, the heat can be directly guided to the outside of the fixed base plate 23 and the guide slide seat 35 through heat transfer, at the same time, the heat-dissipating blade 24 outside the fixed base plate 23 and the heat-conducting blade 31 outside the guide slide seat 35 can be matched with the connecting fan 16 to improve the heat-dissipating efficiency of the new energy vehicle filter 5 due to the maximum transmission.

### Embodiment 3

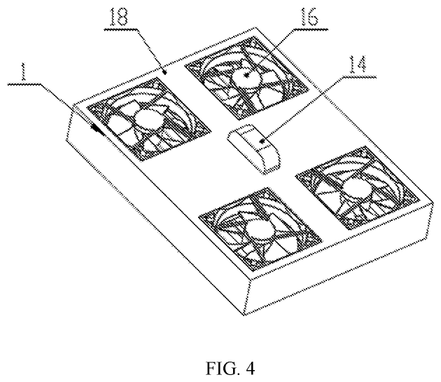

as shown in FIG. 1 to FIG. 4, as a further optimization of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. The guide device 2 comprises a spring snap ring 21, a guide slider 22, a fixed base plate 23, a heat dissipation blade plate 24 and a connecting leg 25, wherein a rear end surface of the fixed base plate 23 is fixedly connected with the heat dissipation blade plate 24 for heat dissipation uniformly and equidistantly, and the guide slider 22 is fixedly connected at a center of an upper end surface of the fixed base plate 23, the spring snap ring 21 is fixedly connected at a center of a front end surface of the guide slider 22, and a lower end surface of the fixed base plate 23 is fixedly connected with the connecting leg 25. The connecting leg 25 can stably limit the bottom of the new energy vehicle filter 5, and the spring snap ring 21 can provide sufficient elastic force for the fixed base plate 23, so that the interior of the fixed base plate 23 can always fit with the interior of the new energy vehicle filter 5, so as to facilitate the subsequent adaptation of different types of the new energy vehicle filter 5, and also improve the stability of the device for limiting the new energy vehicle filter 5.

### Embodiment 4

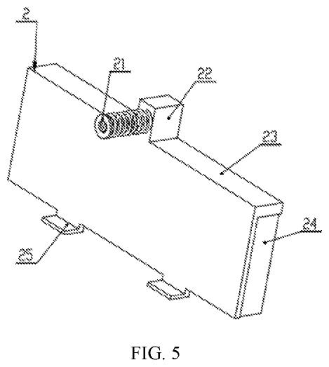

as shown in FIG. 1 to FIG. 5, as a further optimization scheme of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. The guide device 2 comprises a spring snap ring 21, a guide slider 22, a fixed base plate 23, a heat dissipation blade plate 24 and a connecting leg 25, wherein a rear end surface of the fixed base plate 23 is fixedly connected with the heat dissipation blade plate 24 for heat dissipation uniformly and equidistantly, and the guide slider 22 is fixedly connected at a center of an upper end surface of the fixed base plate 23, the spring snap ring 21 is fixedly connected at a center of a front end surface of the guide slider 22, and a lower end surface of the fixed base plate 23 is fixedly connected with the connecting leg 25. The supporting device 3 comprises a heat-conducting blade 31, a connecting spring 32, a supporting slide plate 33, a clamp seat 34 and a guide slide seat 35, wherein a fixed clamp seat 34 is fixedly mounted on the upper end surface of the supporting slide plate 33, and the guide slide seat 35 is symmetrically slidably clamped on an upper end surface of the fixed clamp seat 34; two groups of guide slide seats 35 are elastically fixedly connected through the connecting spring 32, and an upper end surface of the guide slide seat 35 is fixedly connected with a heat conduction blade 31 at uniform and equal intervals. The two groups of guide slide seats 35 can be slidably clamped inside the fixed clamp seat 34, and the two groups of guide slide seats 35 can be elastically connected through the connecting spring 32, so that the two groups of guide slide seats 35 have sufficient limit space, so that the following guide device 2 can conveniently clamp the limit of the new energy vehicle filter 5, and the adaptability of the device is improved.

### Embodiment 5

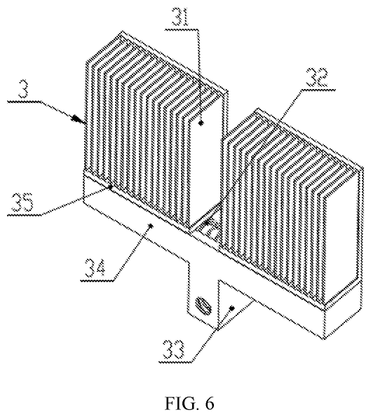

as shown in FIG. 1 to FIG. 6, as a further optimization scheme of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. The guide device 2 comprises a spring snap ring 21, a guide slider 22, a fixed base plate 23, a heat dissipation blade plate 24 and a connecting leg 25, wherein a rear end surface of the fixed base plate 23 is fixedly connected with the heat dissipation blade plate 24 for heat dissipation uniformly and equidistantly, and the guide slider 22 is fixedly connected at a center of an upper end surface of the fixed base plate 23, the spring snap ring 21 is fixedly connected at a center of a front end surface of the guide slider 22, and a lower end surface of the fixed base plate 23 is fixedly connected with the connecting leg 25. The supporting device 3 comprises a heat-conducting blade 31, a connecting spring 32, a supporting slide plate 33, a clamp seat 34 and a guide slide seat 35, wherein a fixed clamp seat 34 is fixedly mounted on the upper end surface of the supporting slide plate 33, and the guide slide seat 35 is symmetrically slidably clamped on an upper end surface of the fixed clamp seat 34; two groups of guide slide seats 35 are elastically fixedly connected through the connecting spring 32, and an upper end surface of the guide slide seat 35 is fixedly connected with a heat conduction blade 31 at uniform and equal intervals. A support shaft is fixedly connected at a center of an inner end surface of the fixed chute 17, and a support guide groove is formed in an inner end surface of the guide slider 22 through inner and outer sides, and the support guide groove is aligned with the spring snap ring 21. The support shaft is aligned with the spring snap ring 21, so that the subsequent spring snap ring 21 can be quickly and stably positioned inside the fixed chute 17. At the same time, the support groove and the support shaft can provide sufficient limit base for the guide slider 22, thereby improving the stability of the subsequent guide device 2 for limiting the new energy vehicle filter 5, and also improving the protection of the new energy vehicle filter 5.

### Embodiment 6

as shown in FIG. 1 to FIG. 6, as a further optimization scheme of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. The guide device 2 comprises a spring snap ring 21, a guide slider 22, a fixed base plate 23, a heat dissipation blade plate 24 and a connecting leg 25, wherein a rear end surface of the fixed base plate 23 is fixedly connected with the heat dissipation blade plate 24 for heat dissipation uniformly and equidistantly, and the guide slider 22 is fixedly connected at a center of an upper end surface of the fixed base plate 23, the spring snap ring 21 is fixedly connected at a center of a front end surface of the guide slider 22, and a lower end surface of the fixed base plate 23 is fixedly connected with the connecting leg 25. The supporting device 3 comprises a heat-conducting blade 31, a connecting spring 32, a supporting slide plate 33, a clamp seat 34 and a guide slide seat 35, wherein a fixed clamp seat 34 is fixedly mounted on the upper end surface of the supporting slide plate 33, and the guide slide seat 35 is symmetrically slidably clamped on an upper end surface of the fixed clamp seat 34; two groups of guide slide seats 35 are elastically fixedly connected through the connecting spring 32, and an upper end surface of the guide slide seat 35 is fixedly connected with a heat conduction blade 31 at uniform and equal intervals. A support shaft is fixedly connected at a center of an inner end surface of the fixed chute 17, and a support guide groove is formed in an inner end surface of the guide slider 22 through inner and outer sides, and the support guide groove is aligned with the spring snap ring 21. The support guide groove is matched with the support shaft, and the guide device 2 is matched with the support shaft through the support guide groove so as to be slidably engaged with the inner end face of the fixed chute 17. The double limit of the support shaft and the support guide groove can effectively improve the stability of the displacement of the guide device 2, and further improve the stability of the limit installation of the new energy vehicle filter 5.

### Embodiment 7

as shown in FIG. 1 to FIG. 6, as a further optimization scheme of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. The guide device 2 comprises a spring snap ring 21, a guide slider 22, a fixed base plate 23, a heat dissipation blade plate 24 and a connecting leg 25, wherein a rear end surface of the fixed base plate 23 is fixedly connected with the heat dissipation blade plate 24 for heat dissipation uniformly and equidistantly, and the guide slider 22 is fixedly connected at a center of an upper end surface of the fixed base plate 23, the spring snap ring 21 is fixedly connected at a center of a front end surface of the guide slider 22, and a lower end surface of the fixed base plate 23 is fixedly connected with the connecting leg 25. The supporting device 3 comprises a heat-conducting blade 31, a connecting spring 32, a supporting slide plate 33, a clamp seat 34 and a guide slide seat 35, wherein a fixed clamp seat 34 is fixedly mounted on the upper end surface of the supporting slide plate 33, and the guide slide seat 35 is symmetrically slidably clamped on an upper end surface of the fixed clamp seat 34; two groups of guide slide seats 35 are elastically fixedly connected through the connecting spring 32, and an upper end surface of the guide slide seat 35 is fixedly connected with a heat conduction blade 31 at uniform and equal intervals. The bevel gear 12 is meshed and rotationally connected with the fixed bevel gear disk 13, and the fixed bevel gear disk 13 is rotationally engaged with the inner end face of the limit chuck 18 by connecting the connecting disk 14. The meshing relationship between the fixed bevel gear disk 13 and the bevel gear 12 can effectively improve the stability and efficiency of the transmission of the connecting screw 15, and further facilitate the stability of the limit of the new energy vehicle filter 5 with different sizes.

### Embodiment 8

as shown in FIG. 1 to FIG. 6, as a further optimization scheme of the above embodiment: the energy consumption filtering device for a new energy electric vehicle based on a SiC module, comprising: a limit device 1, a guide device 2, a support device 3, a mounting support plate 4 and a new energy vehicle filter 5, wherein a lower end face of the limit device 1 is symmetrically engaged with the support device 3 for a limit by sliding thread, and the lower end face of the limit device 1 is symmetrically and elastically engaged with the guide device 2 for the limit by sliding with the guide device 2 as an axis, and a lower end face of the new energy vehicle filter 5 is symmetrically and fixedly connected with the mounting support plate 4 for a connection. The limit device 1 comprises a guide chute 11, a bevel gear 12, a fixed bevel gear disk 13, a connecting disk 14, a connecting screw 15, a connecting fan 16, a fixed chute 17 and a limit chuck 18, a lower end face of the limit chuck 18 is symmetrically provided with the fixed chute 17 for positioning, and the guide chute 11 is symmetrically formed on the lower end surface of the limit chuck 18 with the fixed chute 17 as the axis, an inner end surface of the limit chuck 18 is rotationally clamped with a fixed conical toothed disk 13 for transmission, and the connecting disk 14 is fixedly connected at a center of an upper end surface of the fixed conical toothed disk 13, an upper end surface of the limit chuck 18 is symmetrically clamped with two groups of connecting fans 16, and the inner end surface of the limit chuck 18 is rotationally clamped with the connecting screw 15, and the bevel gear 12 is fixedly installed at a center of a front end face of the connecting screw 15. The guide device 2 comprises a spring snap ring 21, a guide slider 22, a fixed base plate 23, a heat dissipation blade plate 24 and a connecting leg 25, wherein a rear end surface of the fixed base plate 23 is fixedly connected with the heat dissipation blade plate 24 for heat dissipation uniformly and equidistantly, and the guide slider 22 is fixedly connected at a center of an upper end surface of the fixed base plate 23, the spring snap ring 21 is fixedly connected at a center of a front end surface of the guide slider 22, and a lower end surface of the fixed base plate 23 is fixedly connected with the connecting leg 25. The supporting device 3 comprises a heat-conducting blade 31, a connecting spring 32, a supporting slide plate 33, a clamp seat 34 and a guide slide seat 35, wherein a fixed clamp seat 34 is fixedly mounted on the upper end surface of the supporting slide plate 33, and the guide slide seat 35 is symmetrically slidably clamped on an upper end surface of the fixed clamp seat 34; two groups of guide slide seats 35 are elastically fixedly connected through the connecting spring 32, and an upper end surface of the guide slide seat 35 is fixedly connected with a heat conduction blade 31 at uniform and equal intervals. The connecting screw 15 is adapted to the supporting slide plate 33, and the support device 3 is adapted to the supporting slide plate 33 by the connecting screw 15 so as to be slidably engaged with a bottom end surface of the limit chuck 18. The threaded connection between the connecting screw 15 and the support slide plate 33 can facilitate the user to adjust the limit space during the installation of the new energy vehicle filter 5, and the relationship between the threaded connection can effectively improve the accuracy of the limit.

The operating principle of the present disclosure: during installation, the user can align the limit device 1 with the new energy vehicle filter 5, and then position the new energy vehicle filter 5 between the two sets of guide devices 2. At this time, the guide device 2 can be retracted to the inside elastically, and at the same time, the connecting leg 25 at the bottom of the guide device 2 can limit the new energy vehicle filter 5, and then the user can screw the connecting disk 14 as required. When the connecting disk 14 rotates, the connecting disk 14 can drive the fixed conical toothed disk 13 to rotate, and when the fixed conical toothed disk 13 rotates, the fixed conical toothed disk 13 can drive the connecting screw 15 at the side to rotate synchronously. Furthermore, since the connection screw 15 is threadedly connected to the support device 3 from the outside, the user can adjust the specific position of the support device 3 back and forth through the connection rotary table 14 until the rear part of the heat conduction blade 31 is completely clamped and fitted with the new energy vehicle filter 5, thus completing the installation operation and effectively improving the adaptability of the device. In the heat dissipation operation, the users can simultaneously start the four groups of connecting fans 16 through the external control device, and at this time, the connecting fan 16 can rotate at a high speed, thereby blowing heat to the bottom of the limit chuck 18, and at the same time, the rear part of the fixed base plate 23 and the guide slide seat 35 are mortgaged with the outside of the new energy vehicle filter 5, so that the outside of the guide device 2 and the new energy vehicle filter 5 are bonded with the new energy vehicle filter 5, and when the new energy vehicle filter 5 generates a large amount of heat, the heat can be directly guided to the outside of the fixed base plate 23 and the guide slide seat 35 through heat transfer, at the same time, the heat-dissipating blade 24 outside the fixed base plate 23 and the heat-conducting blade 31 outside the guide slide seat 35 can be matched with the connecting fan 16 to improve the heat-dissipating efficiency of the new energy vehicle filter 5 due to the maximum transmission.

It is to be note that that term “include”, “include”, “include” or any other variation thereof is intended to encompass non-exclusive inclusion such that a process, method, article or device comprising a series of elements includes not only those elements, but also other elements not specifically listed, or elements inherent to such a process, method, article or device. Specific examples are used herein to illustrate the principles and embodiments of the present disclosure, and the explanations of the above examples are only used to help understand the method and core ideas of the present disclosure. The above is only a preferred embodiment of the present disclosure. It should be pointed out that because of the limited character expression, there is an infinite specific structure objectively. For those skilled in the art, a number of improvements, modifications or changes may be made without departing from the principles of the present disclosure, and the above technical features may also be combined in an appropriate manner. These improvements, modifications or combinations, or direct application of the inventive concepts and technical solutions to other occasions without improvement, shall be considered as the scope of protection of the present disclosure.

What is claimed is:

1. An energy consumption filtering device for a new energy electric vehicle based on a SiC module, comprising: a limit device, a guide device, a support device, a mounting support plate and a new energy vehicle filter, wherein a lower end face of the limit device is symmetrically engaged with the support device for a limit by sliding thread, the lower end face of the limit device is symmetrically and elastically engaged with the guide device for the limit by sliding with the guide device as an axis, and a lower end face of the new energy vehicle filter is symmetrically and fixedly connected with the mounting support plate for a connection.

2. The energy consumption filter device for the new energy electric vehicle based on the SiC module according to claim 1, wherein the limit device comprises a guide chute, a bevel gear, a fixed bevel gear disk, a connecting disk, a connecting screw, a connecting fan, a fixed chute and a limit chuck, a lower end face of the limit chuck is symmetrically provided with the fixed chute for positioning, and the guide chute is symmetrically formed on the lower end surface of the limit chuck with the fixed chute as the axis, an inner end surface of the limit chuck is rotationally clamped with a fixed conical toothed disk for transmission, and the connecting disk is fixedly connected at a center of an upper end surface of the fixed conical toothed disk, an upper end surface of the limit chuck is symmetrically clamped with two groups of connecting fans, and the inner end surface of the limit chuck is rotationally clamped with the connecting screw, and the bevel gear is fixedly installed at a center of a front end face of the connecting screw.

3. The energy consumption filtering device for the new energy electric vehicle based on the SiC module according to claim 2, wherein the guide device comprises a spring snap ring, a guide slider, a fixed base plate, a heat dissipation blade plate and a connecting leg, wherein a rear end surface of the fixed base plate is fixedly connected with the heat dissipation blade plate for heat dissipation uniformly and equidistantly, and the guide slider is fixedly connected at a center of an upper end surface of the fixed base plate, the spring snap ring is fixedly connected at a center of a front end surface of the guide slider, and a lower end surface of the fixed base plate is fixedly connected with the connecting leg.

4. The energy consumption filtering device for the new energy electric vehicle based on the SiC module according to claim 3, wherein the supporting device comprises a heat-conducting blade, a connecting spring, a supporting slide plate, a clamp seat and a guide slide seat, wherein a fixed clamp seat is fixedly mounted on the upper end surface of the supporting slide plate, and the guide slide seat is symmetrically slidably clamped on an upper end surface of the fixed clamp seat; two groups of guide slide seats are elastically fixedly connected through the connecting spring, and an upper end surface of the guide slide seat is fixedly connected with a heat conduction blade at uniform and equal intervals.

5. The energy consumption filtering device for the new energy electric vehicle based on the SiC module according to claim 4, wherein a support shaft is fixedly connected at a center of an inner end surface of the fixed chute, and a support guide groove is formed in an inner end surface of the guide slider through inner and outer sides, and the support guide groove is aligned with the spring snap ring.

6. The energy consumption filtering device for the new energy electric vehicle based on the SiC module according to claim 5, wherein the support guide groove is matched with the support shaft, and the guide device is matched with the support shaft through the support guide groove so as to be slidably engaged with the inner end face of the fixed chute.

7. The energy consumption filtering device for the new energy electric vehicle based on the SiC module according to claim 4, wherein the bevel gear is meshed and rotationally connected with the fixed bevel gear disk, and the fixed bevel gear disk is rotationally engaged with the inner end face of the limit chuck by connecting the connecting disk.

8. The energy consumption filtering device for the new energy electric vehicle based on the SiC module according to claim 4, wherein the connecting screw is adapted to the supporting slide plate, and the support device is adapted to the supporting slide plate by the connecting screw so as to be slidably engaged with a bottom end surface of the limit chuck.
